(19) United States
(12) Patent Application Publication
(10) Pub. No.: US 2019/0246507 A1
(43) Pub. Date: Aug. 8, 2019

(54) ELECTRONIC DEVICE AND METHOD FOR MANUFACTURING THE SAME

(71) Applicant: KYOCERA Corporation, Kyoto-shi (JP)

(72) Inventor: Shuhei HISANO, Tokyo (JP)

(21) Appl. No.: 16/268,429

(22) Filed: Feb. 5, 2019

(30) Foreign Application Priority Data
Feb. 6, 2018 (JP) 2018-019402

(51) Int. Cl. H05K 5/00; H05K 5/03

(52) U.S. Cl. CPC H05K 5/0017; H04B 1/3827; H05K 5/03

(57) ABSTRACT

An improved electronic device and a method for manufacturing the same are provided. The electronic device is provided with a display, a cover member that covers one surface of the display, a casing, and a first adhesive member. The casing has a peripheral portion that includes a first surface in close contact with the cover member, and an accommodation portion that accommodates the display from the other surface of the display. The first adhesive member is arranged in the first direction between the display and the accommodation portion.

### CROSS REFERENCE TO RELATED APPLICATIONS

The present application claims priority to and the benefit of Japanese Patent Application No. 2018-019402 filed Feb. 6, 2018, the entire contents of which are incorporated herein by reference.

### TECHNICAL FIELD

The present disclosure relates to an electronic device and a method for manufacturing the electronic device.

### BACKGROUND

Conventionally, electronic devices having waterproof structures are known. The electronic device includes a housing having a first surface and a second surface opposite to the first surface, an attached member arranged on the first surface of the housing, double-sided adhesive tape arranged between the first surface of the housing and the attached member, and an adhesive member. In the electronic device, the adhesive member is arranged around the double-sided adhesive tape and thus seals between the first surface of the housing and the attached member.

### SUMMARY

An electronic device according to an embodiment of the present disclosure is provided with a display, a cover member that covers one surface of the display, a casing, and a first adhesive member. The casing has a peripheral portion that includes a first surface in close contact with the cover member and an accommodation portion that accommodates the display from the other surface of the display. The first adhesive member is arranged in a first direction between the display and the accommodation portion.

A method for manufacturing an electronic device according to an embodiment of the present disclosure is provided with mounting, injecting, and curing. In the mounting, a display and a cover member that covers one surface of the display are mounted in a casing. The casing has a peripheral portion that includes a first surface in close contact with the cover member and an accommodation portion that accommodates the display from the other surface of the display. In the injecting, a liquid adhesive is injected into a clearance formed between the display and the accommodation portion. In the curing, the liquid adhesive is cured to form a first adhesive member arranged between the display and the accommodation portion.

### BRIEF DESCRIPTION OF THE DRAWINGS

In the accompanying drawings:

FIG. 1 is an external perspective view of an electronic device according to an embodiment of the present disclosure.

FIG. 2 is a rear view of the electronic device illustrated in FIG. 1.

FIG. 3 is a diagram illustrating a cross-sectional portion of the electronic device taken from line L1-L1 illustrated in FIG. 1.

FIG. 4 is a diagram illustrating a cross-sectional portion of the electronic device taken from line L2-L2 illustrated in FIG. 1.

FIG. 5 is a diagram illustrating a cross-sectional portion of the electronic device taken from line L3-L3 illustrated in FIG. 1.

FIG. 6 is a diagram illustrating a state before a first adhesive member is arranged in a structure illustrated in FIG. 3.

FIG. 7 is a diagram illustrating a state before a first adhesive member is arranged in a structure illustrated in FIG. 4.

FIG. 8 is a diagram illustrating a state before a first adhesive member is arranged in a structure illustrated in FIG. 5.

FIG. 9 is an elevation view of a casing illustrated in FIG. 1.

FIG. 10 is a rear view of the casing illustrated in FIG. 1.

FIG. 11 is a cross-sectional view of the casing taken from line L4-L4 illustrated in FIG. 9.

FIG. 12 is an enlarged view of a portion P1 illustrated in FIG. 9.

FIG. 13 is an enlarged view of a portion P2 illustrated in FIG. 10.

FIG. 14 is a cross-sectional view of the casing taken from line L5-L5 illustrated in FIG. 12.

FIG. 15 is a cross-sectional view of the casing taken from line L6-L6 illustrated in FIG. 12.

FIG. 16 is a diagram illustrating a state in which a front cover is removed from the electronic device illustrated in FIG. 1.

FIG. 17 is a diagram illustrating a state before a double-sided adhesive tape and the first adhesive member are arranged in a structure illustrated in FIG. 16.

FIG. 18 is a cross-sectional view of the electronic device taken from line L7-L7 illustrated in FIG. 16.

FIG. 19 is a flowchart illustrating an example of a method for manufacturing the electronic device illustrated in FIG. 1.

### DETAILED DESCRIPTION

There is room for improvement of conventional electronic devices having waterproof structures.

The present disclosure aims to provide an improved electronic device and a method for manufacturing the electronic device.

According to the present disclosure, an improved electronic device and a method for manufacturing the same may be provided.

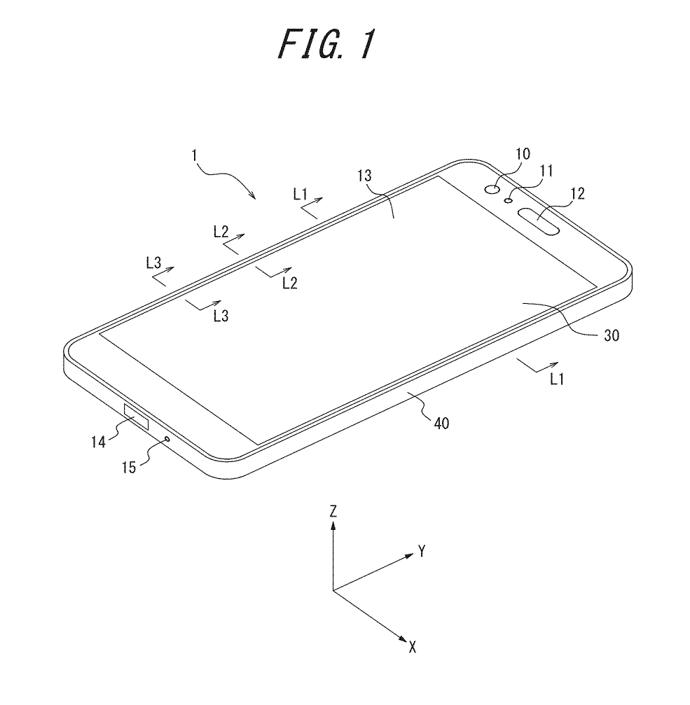

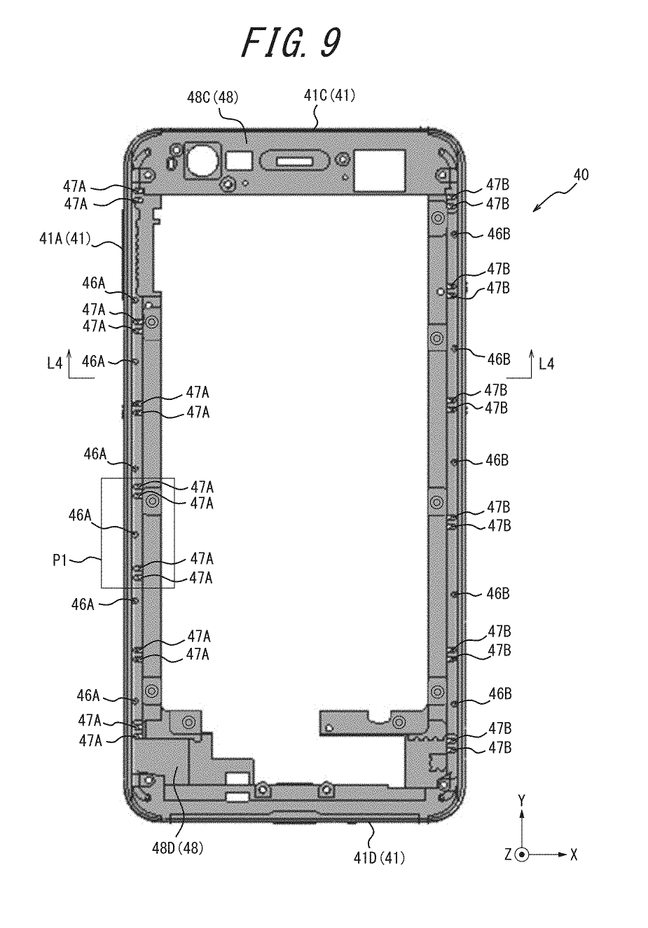

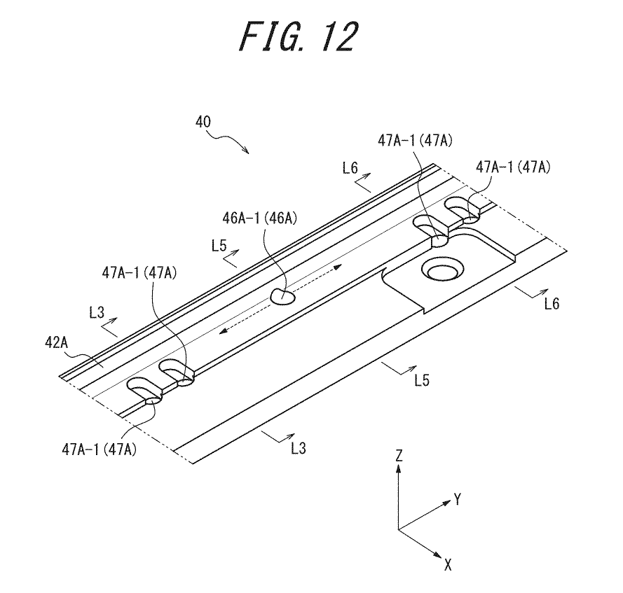

Hereinafter, an electronic device and a method for manufacturing the electronic device according to an embodiment of the present disclosure will be described with reference to FIG. 1 to FIG. 19. Note that the position of the line L1-L1 illustrated in FIG. 1 corresponds to the position of the line L4-L4 illustrated in FIG. 9. The position of the line L2-L2 illustrated in FIG. 1 corresponds to the position of the line L5-L5 illustrated in FIG. 12. The position of the line L3-L3 illustrated in FIG. 1 corresponds to the position of the line L3-L3 illustrated in FIG. 12.

### Electronic Device—Configuration

As illustrated in FIG. 1, the electronic device 1 according to the present embodiment may have a substantially plate-like shape. Hereinafter, in the electronic device 1 having the substantially plate-like shape, a transverse direction, a longitudinal direction, and a thickness direction of the electronic device 1 are referred to as an X-axis direction, a Y-axis direction, and a Z-axis direction, respectively.

Hereinafter, a first direction corresponds to the X-axis direction as the transverse direction of the electronic device 1. Also, a second direction different from the first direction corresponds to the Y-axis direction as the longitudinal direction of the electronic device 1. However, the first direction may be any one of the transverse direction, the longitudinal direction, and the thickness direction of the electronic device 1. For example, the first direction may correspond to the Y-axis direction as the longitudinal direction of the electronic device 1. In this case, the second direction different from the first direction may correspond to the X-axis direction as the transverse direction of the electronic device 1.

The electronic device 1 illustrated in FIG. 1 is a smartphone. However, the electronic device 1 is not limited to a smartphone. For example, the electronic device 1 may be a tablet-type terminal, a mobile phone, a phablet, a tablet computer, a feature phone, a PDA (Personal Digital Assistant), a remote-control terminal, a portable music player, a game machine, an electronic book reader, or the like.

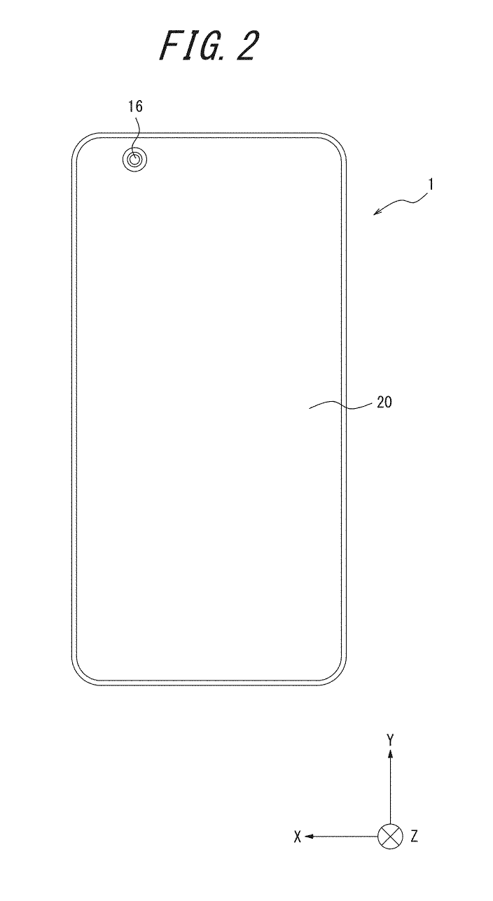

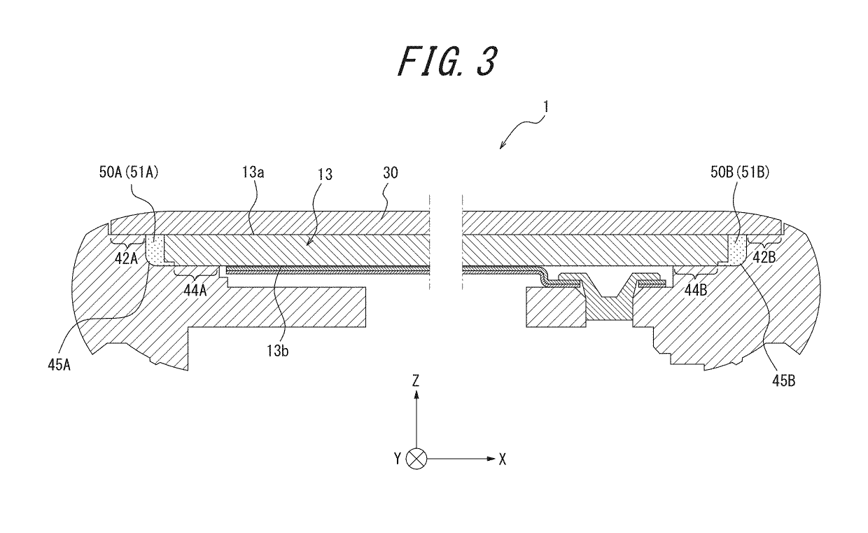

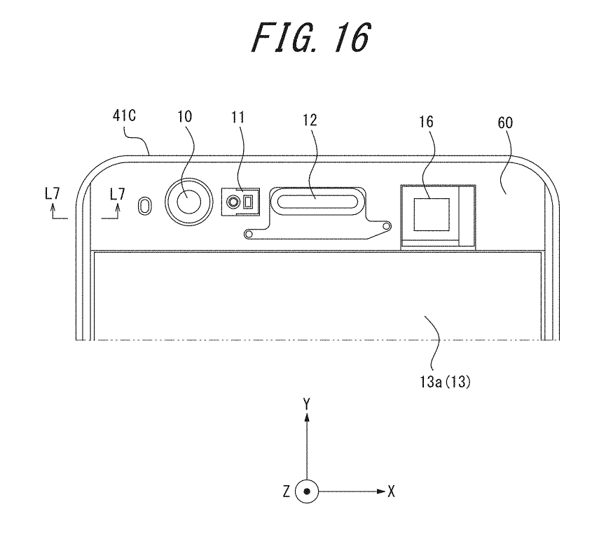

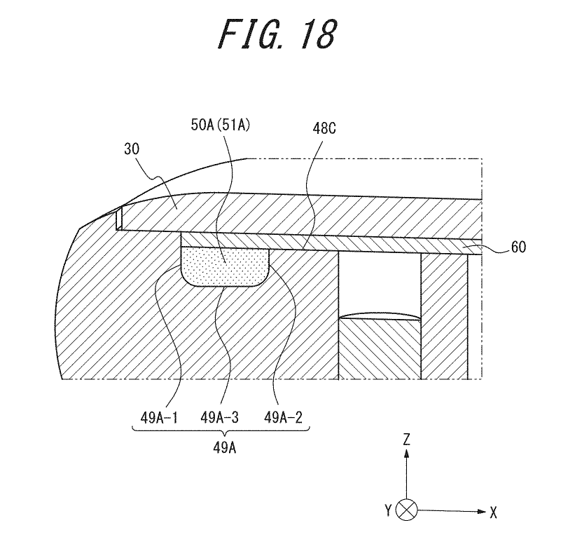

As illustrated in FIG. 1, the electronic device 1 includes a camera 10, a proximity sensor 11, a receiver 12, and a display 13 on the front side thereof. As illustrated in FIG. 1, the electronic device 1 includes an insertion port 14 and a microphone 15 on the bottom side thereof. As illustrated in FIG. 2, the electronic device 1 includes a camera 16 on the rear side thereof. As illustrated in FIG. 1 and FIG. 2, the electronic device 1 includes a rear cover 20, a front cover 30 (a cover member), and a casing 40, which together function as a housing. As illustrated in FIG. 3 to FIG. 5, the electronic device 1 includes first adhesive members 50A and 50B. As illustrated in FIG. 16 and FIG. 18, the electronic device 1 includes a second adhesive member 60.

However, the components of the electronic device 1 is not limited to the above components. The electronic device 1 may include any appropriate components. For example, the electronic device 1 may include a controller, a memory, and a battery. The controller controls the electronic device 1 in its entirety. The controller may include one or more processors. For example, the controller may include a general-purpose processor that loads a specific program and performs a specific function, and a specialized processor dedicated for a specific processing. The memory stores programs to be executed by the controller. The memory may include a semiconductor memory and a magnetic memory. The battery may supply power to at least one component of the electronic device 1.

The camera 10 illustrated in FIG. 1 photographs an object facing the front cover 30. The camera 10 may be a digital camera.

The proximity sensor 11 illustrated in FIG. 1 detects the presence of a neighboring object in a contactless manner. For example, the proximity sensor 11 detects a face of a user, as the neighboring object, who is talking on the electronic device 1. The controller of the electronic device 1 turns off the screen of the display 13 when the proximity sensor 11 detects the presence of the neighboring object.

The receiver 12 illustrated in FIG. 1 converts a voice signal transmitted from the controller of the electronic device 1 into voice and outputs the voice. The receiver 12 may output the voice of the other party during a call.

The display 13 illustrated in FIG. 1 may include an LCD (Liquid Crystal Display), an organic EL (Electro Luminescent) display, an inorganic EL display, or the like. The display 13 may include, for example, a sheet metal for reinforcement thereof.

The display 13 may be a touchscreen display. The touchscreen display detects a contact made by a finger, a stylus pen or the like and identifies a contact position.

As illustrated in FIG. 1, the display 13 may have a plate-like shape substantially parallel to an XY plane. As illustrated in FIG. 3, the display 13 having the plate-like shape may include two surfaces substantially parallel to the XY plane. Between the two surfaces of the display 13 substantially parallel to the XY plane, the surface located on the positive direction side of the Z-axis is referred to as “surface 13a”, and the surface located on the negative direction side of the Z-axis is referred to as “surface 13b”.

A plug connector may be inserted into an insertion port 14 illustrated in FIG. 1. The electronic device 1 may be electrically coupled to an external device via the plug connector inserted into the insertion port 14.

The microphone 15 illustrated in FIG. 1 collects the user's voice and nearby sound during a call. The microphone 15 converts the collected sound into an electric signal and outputs the electric signal to the controller of the electronic device 1.

The camera 16 illustrated in FIG. 2 photographs an object facing the rear cover 20. The camera 16 may be a digital camera.

The rear cover 20 illustrated in FIG. 2 may be made of any material. The material may include a metal and a synthetic resin. The rear cover 20 may be integrally formed with the casing 40 illustrated in FIG. 1. In this case, the rear cover 20 may be a part of the casing 40.

The front cover 30 illustrated in FIG. 1 may be made of any material. The material may include glass and a synthetic resin. At least a part of the front cover 30 may have transparency.

The front cover 30 covers one of the surfaces of the display 13. As illustrated in FIG. 3, for example, the front cover 30 covers the surface 13a of the display 13. The surface facing the surface 13a of the front cover 30 may be substantially parallel to the XY plane so as to be in close contact with the surface 13a of the display 13.

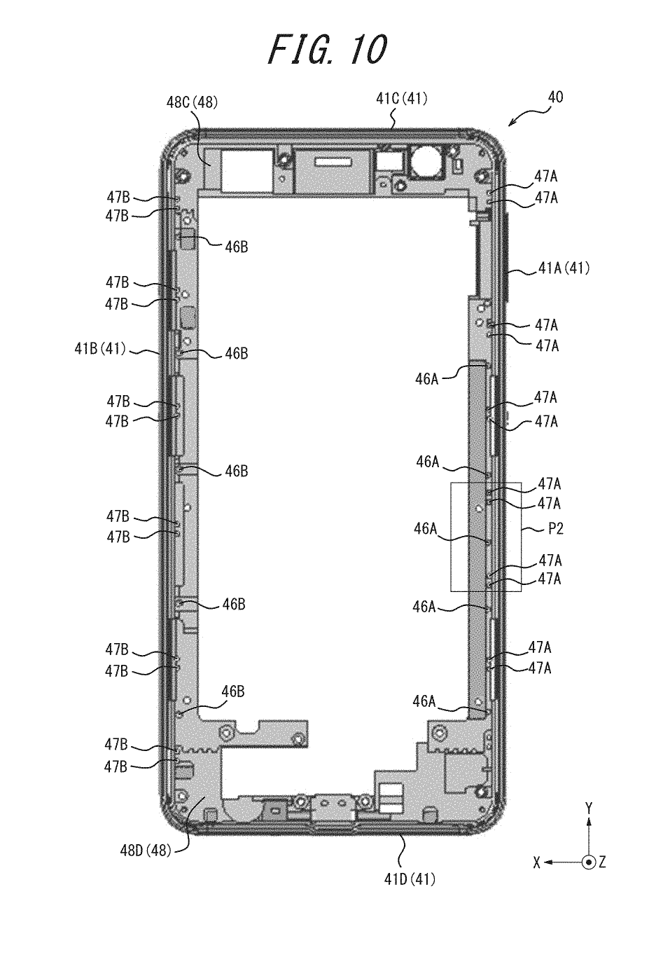

The casing 40 illustrated in FIG. 9 and FIG. 10 may support or accommodate any component of the electronic device 1. The casing 40 may be made of any material. The material may include metal and a synthetic resin.

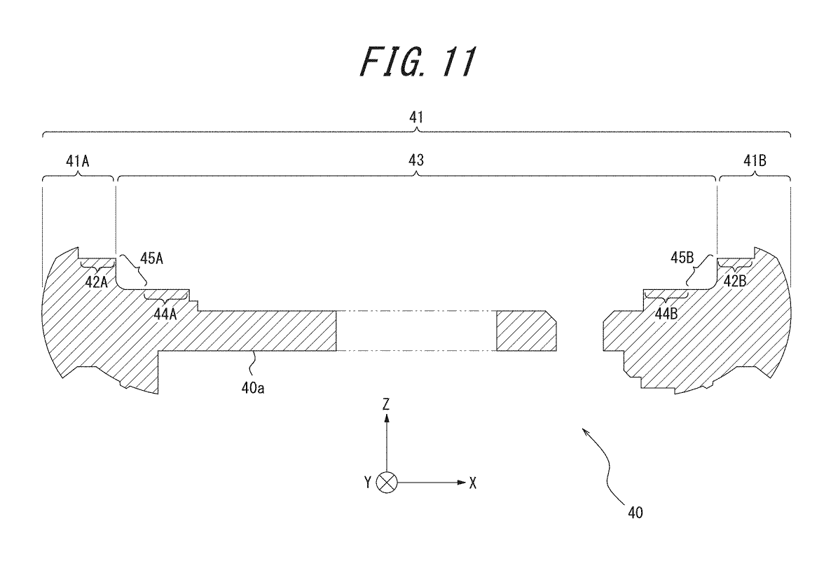

As illustrated in FIG. 9 and FIG. 10, the casing 40 may be substantially parallel to the XY plane. As illustrated in FIG. 11, the casing 40 may have a peripheral portion 41, an accommodation portion 43, and an outer surface 40a located opposite to the accommodation portion 43. As illustrated in FIG. 9 and FIG. 10, further, the casing 40 may include first through holes 46A and 46B, second through holes 47A and 47B, and a base 48.

The peripheral portion 41 includes peripheral portions 41A and 41B as illustrated in FIG. 11. As illustrated in FIG. 9 and FIG. 10, the peripheral portion 41 further includes peripheral portions 41C and 41D. In the peripheral portion 41, the peripheral portion 41A is a portion that is substantially parallel to the Y-axis and located on the negative direction side of the X-axis. In the peripheral portion 41, the peripheral portion 41B is a portion that is substantially parallel to the Y-axis and located on the positive direction side of the X-axis. In the peripheral portion 41, the peripheral portion 41C is a portion that is substantially parallel to the X-axis and located on the positive direction side of the Y-axis. In the peripheral portion 41, the peripheral portion 41D is a portion that is substantially parallel to the X-axis and located on the negative direction side of the Y-axis.

The peripheral portion 41A includes a first surface 42A. The peripheral portion 41B includes a first surface 42B. As illustrated in FIG. 3, each of the first surface 42A and the first surface 42B is in close contact with the front cover 30. The first surfaces 42A and 42B may be surfaces substantially parallel to the XY plane. In a similar manner to the peripheral portion 41A and the like, each of the peripheral portions 41C and 41D includes a first face that is in close contact with the front cover 30.

The accommodation portion 43 illustrated in FIG. 11 accommodates the display 13 from the other surface of the display 13 (i.e. a surface of the display 13 other than the surface 13a). As illustrated in FIG. 3, for example, the accommodation portion 43 accommodates the display 13 from the surface 13b of the display 13.

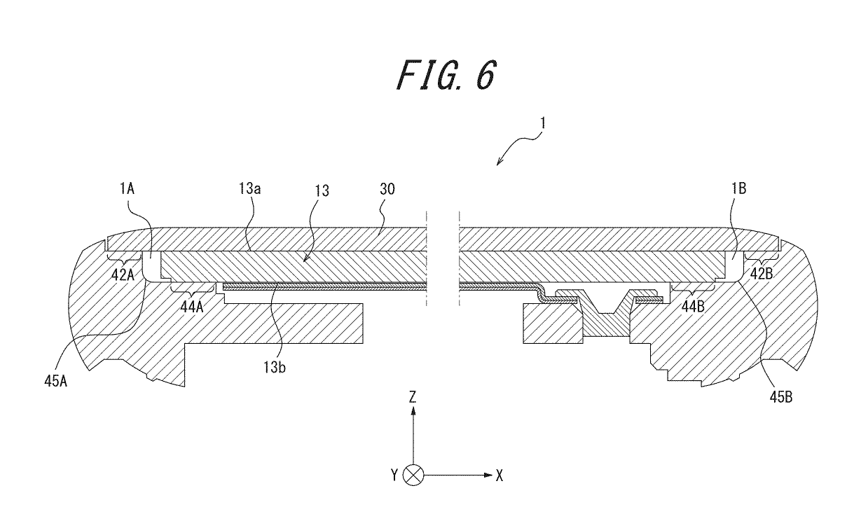

The accommodation portion 43 may be shaped to form clearances 1A and 1B illustrated in FIG. 6 when the display 13 and the front cover 30 are mounted in the casing 40 in the manufacturing process of the electronic device 1. The clearance 1A is a gap formed between the display 13 and the accommodation portion 43 on the negative direction side of the X-axis. The clearance 1B is a gap formed between the display 13 and the accommodation portion 43 on the positive direction side of the X-axis. The clearances 1A and 1B may be sized in accordance with a design accuracy of the display 13 and the casing 40. As illustrated in FIG. 11, the accommodation portion 43 may include second surfaces 44A and 44B and third surfaces 45A and 45B such that the clearances 1A and 1B may be formed.

Each of the second surfaces 44A and 44B illustrated in FIG. 11 is in close contact with the other surface of the display 13. As illustrated in FIG. 3, for example, the second surface 44A is in close contact with a part of the surface 13b of the display 13 located on the negative direction side of the X-axis. As illustrated in FIG. 3, for example, the second surface 44B is in close contact with another part of the surface 13b of the display 13 located on the positive direction side of the X-axis. The second surfaces 44A and 44B may be substantially parallel to the XY plane so as to be in close contact with the surface 13b of the display 13.

The third surface 45A illustrated in FIG. 11 couples the first surface 42A and the second surface 44A together. For example, the third surface 45A has a surface that is substantially parallel to the ZY plane and communicates with the edge of the first surface 42A, a surface that is substantially parallel to the XY plane and communicates with the edge of the second surface 44A, and a curved surface that couples the surface substantially parallel to the ZY plane and the surface substantially parallel to the XY plane together.

The third surface 45B illustrated in FIG. 11 couples the first surface 42B and the second surface 44B together. For example, the third surface 45B has a surface that is substantially parallel to the ZY plane and communicates with the edge of the first surface 42B, a surface substantially that is parallel to the XY plane and communicates with the edge of the second surface 44B, and a curved surface that couples the surface substantially parallel to the ZY plane and the surface substantially parallel to the XY plane together.

When the display 13 is mounted in the casing 40 having the second surfaces 44A and 44B and the third surfaces 45A and 45B as described above in the manufacturing process of the electronic device 1, the clearances 1A and 1B illustrated in FIG. 6 may be formed.

As illustrated in FIG. 9, the first through holes 46A are provided to the casing 40 on the negative direction side of the X-axis. As illustrated in FIG. 9, the first through holes 46B are provided to the casing 40 on the positive direction side of the X-axis. A plurality of first through holes 46A and 46B may be provided to the casing 40.

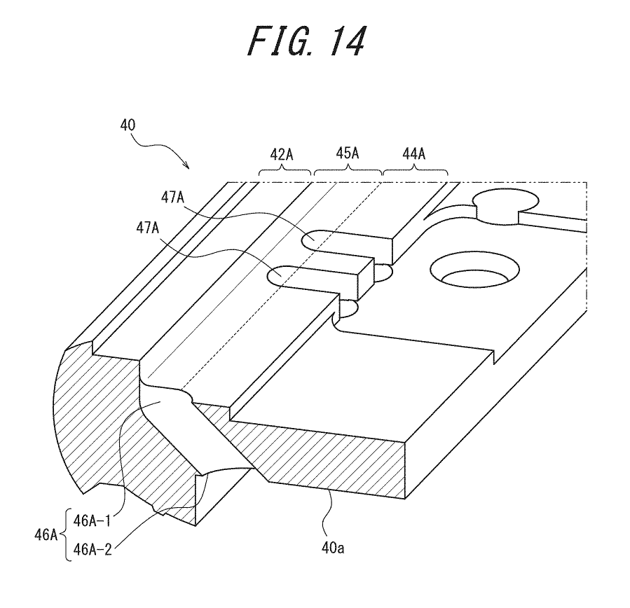

As illustrated in FIG. 14, the first through holes 46A communicate with the outer surface 40a and the third surface 45A. In a manner similar to the first through holes 46A, the first through holes 46B communicate with the outer surface 40a and the third surface 45B.

In the manufacturing process of the electronic device 1, the first through holes 46A are used to form the first adhesive member 50A illustrated in FIG. 3 within the clearance 1A illustrated in FIG. 6. The first through holes 46B are used to form the first adhesive member 50B illustrated in FIG. 3.

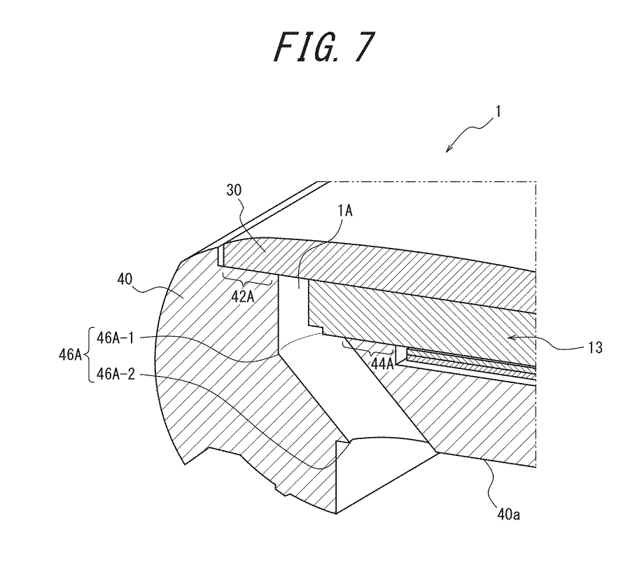

As illustrated in FIG. 14, each of the first through holes 46A includes an opening 46A-1 on the third surface 45A and an opening 46A-2 on the outer surface 40a. When the display 13 and the front cover 30 are mounted in the casing 40 in the manufacturing process of the electronic device 1, the opening 46A-1 communicates with the clearance 1A as illustrated in FIG. 7. In a manner similar to the first through holes 46A, each of the first through holes 46B includes an opening on the third surface 45B and an opening on the outer surface 40a. When the display 13 and the front cover 30 are mounted in the casing 40 in the manufacturing process of the electronic device 1, the opening on the third surface 45B communicates with the clearance 1B illustrated in FIG. 6.

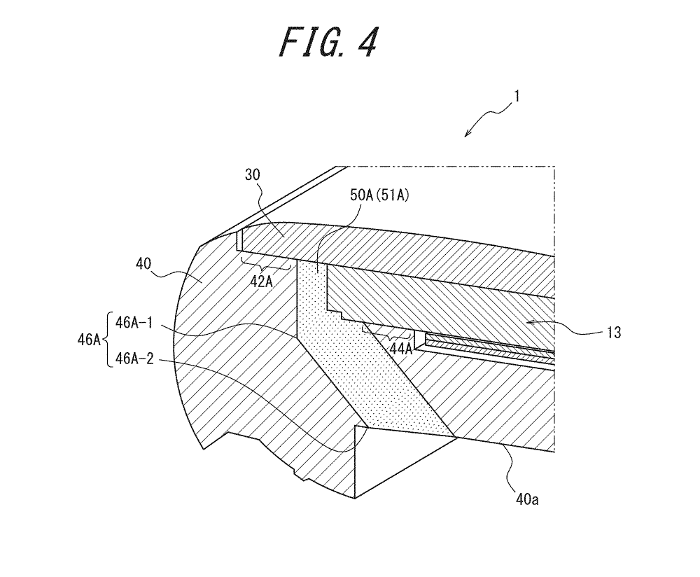

After the display 13 is mounted in the casing 40 in the manufacturing process of the electronic device 1, a liquid adhesive 51A is injected through the opening 46A-2 illustrated in FIG. 7. When the liquid adhesive 51A, which will be described later, is cured, the first adhesive member 50A is formed as illustrated in FIG. 3 and FIG. 4. The liquid adhesive 51A injected through the opening 46A-2 illustrated in FIG. 7 overflows from the opening 46A-1 illustrated in FIG. 12. The liquid adhesive 51A overflowing from the opening 46A-1 spreads in the positive and negative directions of the Y-axis, as indicated by the dashed arrows in FIG. 12. When the liquid adhesive 51A overflowing from the opening 46A-1 illustrated in FIG. 12 spreads in the positive and negative directions of the Y-axis as described above, the clearance 1A illustrated in FIG. 6 is filled with the liquid adhesive 51A. When the liquid adhesive 51A filling in the clearance 1A illustrated in FIG. 6 is cured, the first adhesive member 50A is formed as illustrated in FIG. 3 and FIG. 4.

In a manner similar to the opening 46A-2 illustrated in FIG. 7, after the display 13 is mounted in the casing 40 in the manufacturing process of the electronic device 1, the liquid adhesive 51B is injected through the opening of the first through hole 46B on the outer surface 40a. In the same manner as described above, when the liquid adhesive 51B filling in the clearance 1B illustrated in FIG. 6 is cured, the first adhesive member 50B is formed as illustrated in FIG. 3.

As illustrated in FIG. 9, the second through holes 47A are provided to the casing 40 on the negative direction side of the X-axis. As illustrated in FIG. 9, the second through holes 47B are provided to the casing 40 on the positive direction side of the X-axis. A plurality of second through holes 47A and 47B may be provided to the casing 40.

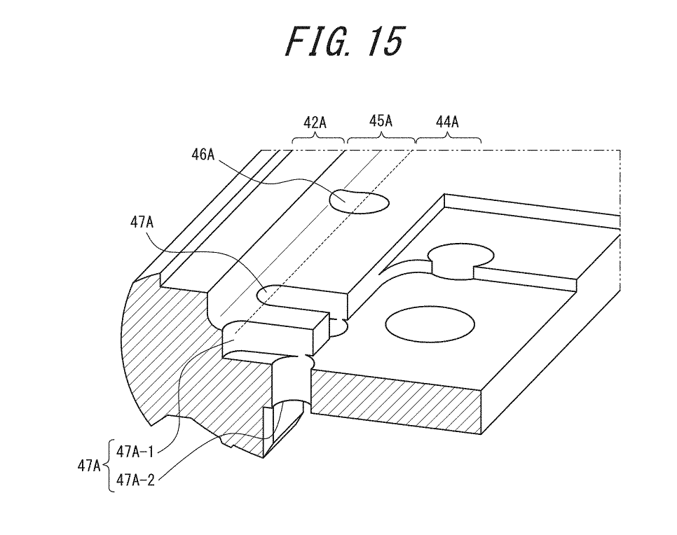

As illustrated in FIG. 15, the second through holes 47A communicate with the outer surface 40a and the third surface 45A. In a manner similar to the second through hole 47A, the second through holes 47B communicate with the outer surface 40a and the third surface 45B.

The second through holes 47A are used to enable confirmation as to whether the liquid adhesive 51A injected through the first through hole 46A is filled in the clearance 1A in the manufacturing process of the electronic device 1. The second through holes 47B are used to enable confirmation as to whether the liquid adhesive 51B injected through the first through holes 46B is filled in the clearance 1B in the manufacturing process of the electronic device 1.

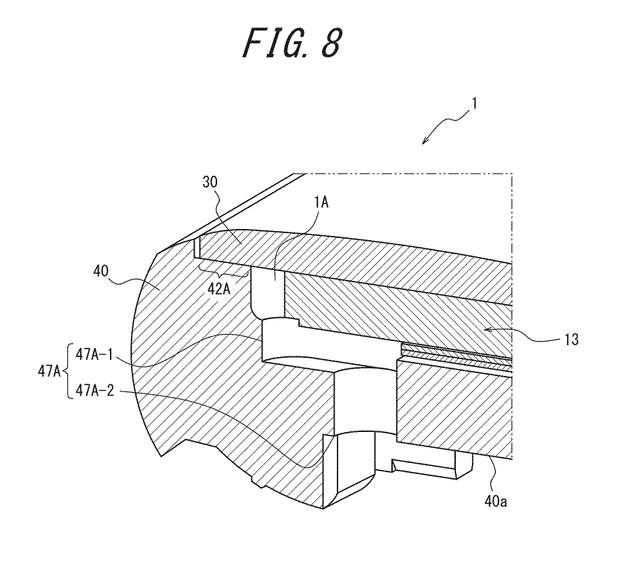

As illustrated in FIG. 15, each of the second through holes 47A includes an opening 47A-1 on the third surface 45A and an opening 47A-2 on the outer surface 40a. In the manufacturing process of the electronic device 1, the opening 47A-1 communicates with the clearance 1A as illustrated in FIG. 8. In a manner similar to the second through hole 47A, the second through hole 47B includes an opening on the third surface 45B and an opening on the outer surface 40a. In the manufacturing process of the electronic device 1, the opening on the third surface 45B communicates with the clearance 1B illustrated in FIG. 6.

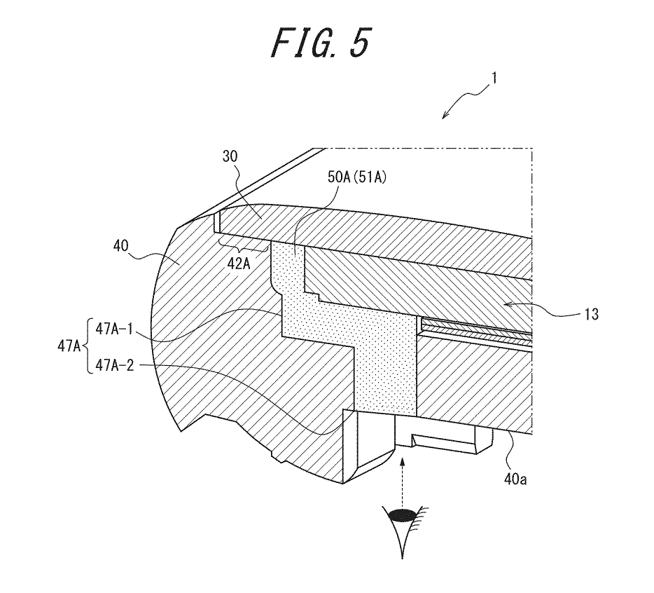

As described above, in the manufacturing process of the electronic device 1, the liquid adhesive 51A is injected through the opening 46A-2 of the first through hole 46A illustrated in FIG. 7. The liquid adhesive 51A injected through the opening 46A-2 illustrated in FIG. 7 overflows from the opening 46A-1 illustrated in FIG. 12 and spreads in the positive and negative directions of the Y-axis. The liquid adhesive 51A spreading in the positive direction of the Y-axis from the opening 46A-1 illustrated in FIG. 12 flows into the opening 47A-1 of the second through hole 47A located on the positive direction side of the Y-axis with respect to the opening 46A-1. On the other hand, the liquid adhesive 51A spreading in the negative direction of the Y-axis from the opening 46A-1 illustrated in FIG. 12 flows into the opening 47A-1 located on the negative direction side of the Y-axis with respect to the opening 46A-1. Here, the liquid adhesive 51A flowing into the opening 47A-1 may reach the vicinity of the opening 47A-2 as illustrated in FIG. 5. That is, the liquid adhesive 51A is visible from the opening 47A-2, thus enabling confirmation as to whether the liquid adhesive 51A is filled in the clearance 1A.

In a manner similar to the opening 47A-2 described above, the liquid adhesive 51B is visible from the second through hole 47B-2, thus enabling confirmation as to whether the liquid adhesive 51B is filled in the clearance 51B.

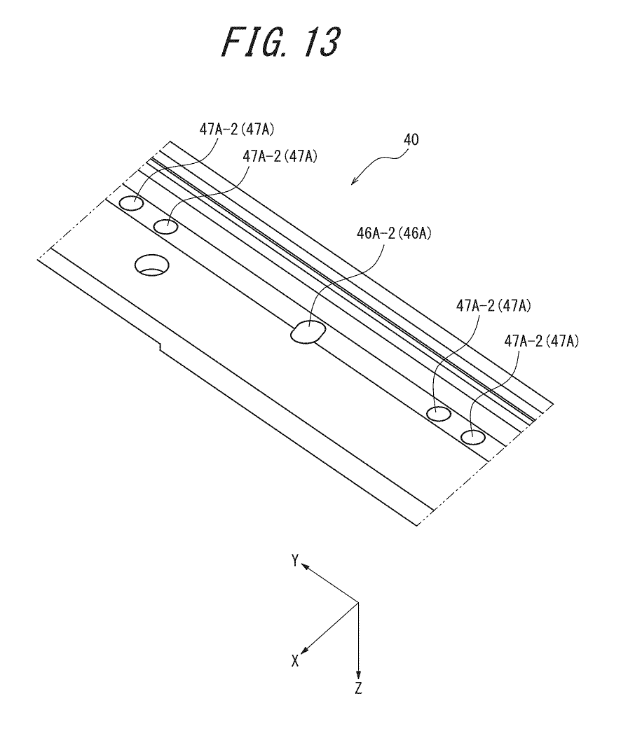

The area of the opening 47A-2 of each of the second through holes 47A illustrated in FIG. 13 may be smaller than the area of the opening 46A-2 of each of the first through holes 46A illustrated in FIG. 13. This reduces the probability that the liquid adhesive 51A leaks out from the openings 47A-2 when the liquid adhesive 51A is filled in the clearance 1A in the manufacturing process of the electronic device 1. The first through holes 46B and the second through holes 47B may have the same configurations as the first through holes 46A and the second through holes 47A, respectively.

The area of the opening 47A-2 of each of the second through holes 47A illustrated in FIG. 8 may be smaller than the area of the opening 47A-1 of each of the second through holes 47A illustrated in FIG. 8. When the area of the opening 47A-2 is smaller than the area of the opening portion 47A-1, the probability that the liquid adhesive 51A leaks out from the opening portion 47A-2 in the manufacturing process of the electronic device 1 may be reduced. The second through holes 47B may have the same configuration as the second through holes 47A.

For example, the opening 47A-1 of each of the second through holes 47A illustrated in FIG. 8 may have a concave shape opening toward the front cover 30. In this case, the area of the opening portion 47A-2 may be smaller than the area of the opening portion of the opening 47A-1 having the concave shape. Thus, the area of the opening 47A-2 may be smaller than the area of the opening 47A-1. When the area of the opening 47A-2 is smaller than the area of the opening 47A-1 as described above, the probability that the liquid adhesive 51A leaks out from the opening 47A-2 in the manufacturing process of the electronic device 1 may be reduced. Further, the opening 47A-1 having a concave shape that opens toward the front cover 30 facilitates the flow of the liquid adhesive 51A into the opening 47A-1 in the manufacturing process of the electronic device 1. Facilitating the flow of the liquid adhesive 51A into the opening 47A-1 improves the visibility of the liquid adhesive 51A through the opening 47A-2. The second through holes 47b may have the same configuration as the second through holes 47A.

For example, each of the second through hole 47A may be gradually enlarged from the outer surface 40a toward the third surface 45A. This configuration may make the area of the opening 47A-2 smaller than the area of the opening 47A-1. When the area of the opening 47A-2 is smaller than the area of the opening 47A-1 as described above, the probability that the liquid adhesive 51A leaks out from the opening 47A-2 in the manufacturing process of the electronic device 1 may be reduced. Further, the shape of the second through hole 47A gradually enlarged from the outer surface 40a toward the third surface 45A facilitates the flow of the liquid adhesive 51A into the opening 47A-1 in the manufacturing process of the electronic device 1. Facilitating the flow of the liquid adhesive 51A into the opening 47A-1 improves the visibility of the liquid adhesive 51A through the opening 47A-2. The second through holes 47B may have the same configuration as the second through holes 47A.

The base 48 illustrated in FIG. 9 is located between the peripheral portion 41 and the accommodation portion 43 in the second direction different from the first direction, i.e., in the Y-axis direction according to the present embodiment. As illustrated in FIG. 9, the base 48 may include a base portion 48C and a base portion 48D.

The base portion 48C is located between the peripheral portion 41C and the accommodation portion 43. The base portion 48D is located between the peripheral portion 41D and the accommodation portion 43. Each of the base portions 48C and 48D may have various components mounted thereon. For example, the base portion 48C has the camera 10, the proximity sensor 11, and the receiver 12 mounted thereon. The base portion 48C also has the camera 16 illustrated in FIG. 2 mounted thereon. For example, the base portion 48D has the microphone 15 illustrated in FIG. 1 mounted thereon.

The front cover 30 may be attached to the base portion 48C illustrated in FIG. 18 via the second adhesive member 60. In a manner similar to the base portion 48C, the front cover 30 may be attached to the base portion 48D via the second adhesive member 60.

Hereinafter, among the two surfaces of the base portion 48C that are substantially parallel to the XY plane, the surface positioned in the positive direction side of the Z-axis will be referred to as a “surface 48a”.

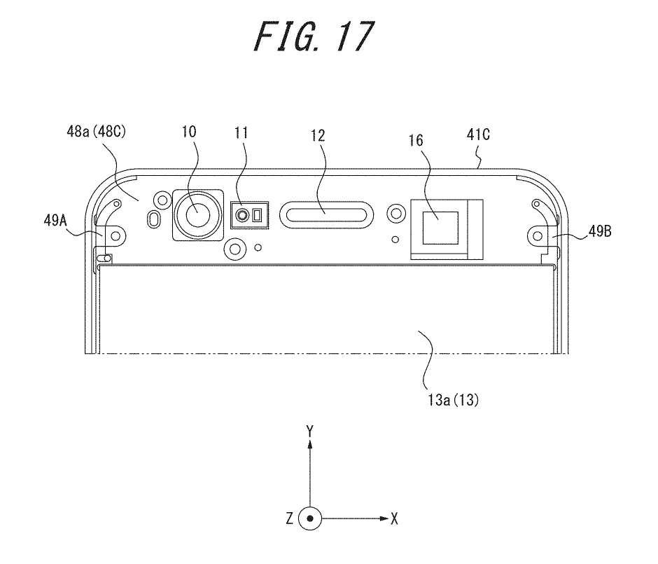

In the Z-axis direction, the height of the surface 48a illustrated in FIG. 17 may be substantially the same as the height of the surface 13a of the display 13. This configuration may reduce a gap between the surface 48a of the base portion 48C, the surface 13a of the display 13, and the front cover 30. Note that, when the height of the surface 48a and the height of the surface 13a are substantially equal to each other, the surface 48a illustrated in FIG. 17 may be located on the positive side of the Z-axis with respect to the second surfaces 44A and 44B illustrated in FIG. 3.

The base portion 48C illustrated in FIG. 17 may include a groove 49A and a groove 49B. The groove 49A illustrated in FIG. 17 may be formed by extending the third surface 45A illustrated in FIG. 3 in the positive direction of the Y-axis. The groove 49B illustrated in FIG. 17 may be formed by extending the third surface 45B illustrated in FIG. 3 in the positive direction of the Y-axis. In a manner similar to the base portion 48C, the base portion 48D may include a groove formed by extending the third surface 45A in the negative direction of the Y-axis and a groove formed by extending the third surface 45B in the negative direction of the Y-axis.

As illustrated in FIG. 18, for example, the groove 49A may include walls 49A-1 and 49A-2 substantially parallel to the Z-axis and a bottom 49A-3 located between the wall 49A-1 and the wall 49A-2. In this case, the wall 49A-1 and the bottom 49A-3 may be formed by extending the third surface 45A illustrated in FIG. 3 in the positive direction of the Y-axis. In a manner similar to the groove 49A, the groove 49B illustrated in FIG. 17 may include two walls substantially parallel to the Z-axis and a bottom located between the two walls. One of the walls and the bottom of the groove 49B may be formed by extending the third surface 45B illustrated in FIG. 3 in the positive direction of the Y-axis.

In a case in which the groove 49A is formed by extending the third surface 45A illustrated in FIG. 3, the groove portion 49A illustrated in FIG. 17 and the clearance 1A illustrated in FIG. 6 may communicate with each other when the display 13 and the like are mounted in the casing 40 in the manufacturing process of the electronic device 1. In the manufacturing process of the electronic device 1, when the groove 49A and the clearance 1A communicate with each other, the adhesive member 50A may be formed (arranged) in the groove 49 A as illustrated in FIG. 18, as will be described later.

As described above, for example, the liquid adhesive 51A is injected into the clearance 1A through the opening 46A-2 illustrated in FIG. 7 in the manufacturing process of the electronic device 1. When the liquid adhesive 51A is injected into the clearance 1A, the liquid adhesive 51A is also injected into the groove 49A communicating with the clearance 1A. When the liquid adhesive 51A is injected into the groove 49A, the liquid adhesive 51A is filled in the groove 49A. When the liquid adhesive 51A filled in the groove 49A is cured, the adhesive member 50A is formed (arranged) in the groove 49A.

In a manner similar to the groove 49A, the groove 49B is formed by extending the third surface 45B illustrated in FIG. 3, and thus the adhesive member 50B may be formed (arranged) in the groove 49B.

The bottom 49A-3 illustrated in FIG. 18 may be inclined with respect to the XY plane or substantially parallel to the XY plane, depending on the property of the liquid adhesive 51A. Similarly, the bottom portion of the groove 49B may be inclined with respect to the XY plane or substantially parallel to the XY plane, depending on the property of the liquid adhesive 51B.

For example, when the liquid adhesive 51A has high viscosity, the bottom 49A-3 may be inclined with respect to the XY plane toward the positive or negative direction side of the Z-axis, as located closer to the peripheral portion 41C from the display 13 illustrated in FIG. 17. The inclination of the bottom 49A-3, even when the liquid adhesive 51A has high viscosity, facilitates the flow of the liquid adhesive 51A to the end of the groove 49A in the manufacturing process of the electronic device 1. That is, the liquid adhesive 51A may be easily filled up to the end of the groove 49A. The groove 49B may have the same configuration.

For example, the bottom 49A-3 may be substantially parallel to the XY plane, depending on the characteristics of the liquid adhesive 51A. When the bottom 49A-3 is substantially parallel to the XY plane, the liquid adhesive 51A may be easily filled in the groove 49A in a uniform manner in the manufacturing process of the electronic device 1. The groove 49B may have the same configuration.

As illustrated in FIG. 17, the groove 49A may be formed along a corner on the negative direction side of the X-axis of the electronic device 1 having a plate-like shape. As illustrated in FIG. 17, the groove 49B may be formed along a corner on the positive direction side of the X-axis of the electronic device 1 having the plate-like shape. This configuration may reduce the probability of damaging the electronic device 1 when, for example, the electronic device 1 is dropped and a corner of the electronic device 1 hits the ground or the like.

The adhesive members 50A and 50B illustrated in FIG. 3 are arranged between the display 13 and the casing 40 in the X-axis direction. As illustrated in FIG. 3, for example, the adhesive member 50A is arranged between the third surface 45A and the surface of the display 13 facing the third surface 45A. As illustrated in FIG. 3, for example, the adhesive member 50B is arranged between the third surface 45B and the surface of the display 13 facing the third surface 45B. This configuration may reduce the probability that the water enters the electronic device 1 from the outside thereof.

The adhesive member 50A may be formed by curing the liquid adhesive 51A in the manufacturing process of the electronic device 1. Similarly, the adhesive member 50B may be formed by curing the liquid adhesive 51B in the manufacturing process of the electronic device 1.

The liquid adhesives 51A and 51B may be of any type. For example, the liquid adhesives 51A and 51B may be moisture-curable adhesives, heat curable adhesives, or ultraviolet curable adhesives. Moisture-curable adhesives cure by reacting with moisture in the air. Moisture-curable adhesives may include a cyanoacrylate adhesive and a silicone rubber adhesive. Thermosetting adhesives are cured when heated. Thermosetting adhesives may include an epoxy resin and an acrylic resin. The ultraviolet curable adhesives are cured when being irradiated with the ultraviolet rays. The ultraviolet curable adhesives may include an acrylic resin and an epoxy-based adhesive.

The second adhesive member 60 illustrated in FIG. 18 adheres the base 48C and the front cover 30 together. The second adhesive member 60 is arranged on the surface 48a of the base portion 48C. The second adhesive member 60 may be double-sided adhesive tape as illustrated in FIG. 16. However, the second adhesive member 60 is not limited to double-sided adhesive tape. The second adhesive member 60 may be any adhesive member.

As described above, in the electronic device 1 according to the present embodiment, the first adhesive members 50A and 50B are arranged between the display 13 and the accommodation portion 43. According to the present embodiment, thus, the probability that the water enters the electronic device 1 from the outside thereof may be reduced. In the electronic device 1 according to the present embodiment, further, the first adhesive members 50A and 50B are provided in the clearances 1A and 1B as illustrated in FIG. 6 formed in the manufacturing process of the electronic device 1. This configuration of the electronic device 1 according to the present embodiment eliminates the necessity to provide dedicated spaces for arranging the first adhesive members 50A and 50B in the casing 40 or the like. Thus, the electronic device 1 according to the present embodiment may be downsized while maintaining the size of the display 13. In the electronic device 1 according to the present embodiment, further, the size of the display 13 may be increased while maintaining the size of the electronic device 1. According to the present disclosure, in other words, the electronic device 1 having a small frame width surrounding the display 13, i.e., a so-called small-width bezel, may be provided. Thus, the present disclosure may provide an improved electronic device 1.

Further, in the electronic device 1 according to the present embodiment, the second surface 44A of the casing 40 is in close contact with a part of the surface 13b of the display 13 located on the negative direction side of the X-axis, as illustrated in FIG. 3. This configuration may reduce, in the manufacturing process of the electronic device 1, the probability that the liquid adhesive 51A flows under the surface 13b of the display 13 when the liquid adhesive 51A is injected into the clearance 1A illustrated in FIG. 6. In the electronic device 1 according to the present embodiment, similarly, the second surface 44B of the casing 40 is in close contact with a part of the surface 13b of the display 13 located on the positive direction side of the X-axis, as illustrated in FIG. 3. This configuration may reduce, in the manufacturing process of the electronic device 1, the probability that the liquid adhesive 51B flows under the surface 13b of the display 13 when the liquid adhesive 51B is injected into the clearance 1B illustrated in FIG. 6.

Here, various components may be mounted on the base portions 48C and 48D illustrated in FIG. 9, as described above. In some cases, thus, locations on the base portions 48C, 48D to provide the first through holes 46A and 46B described above may be limited. In this case also, in the electronic device 1 according to the present embodiment, the groove 49A and the groove 49B may be formed on the base 48C, as illustrated in FIG. 17. In the manufacturing process of the electronic device 1, the groove portion 49A illustrated in FIG. 17 communicates with the clearance 1A illustrated in FIG. 6, and the groove portion 49B illustrated in FIG. 17 communicates with the clearance 1B illustrated in FIG. 6. This configuration enables, without forming the first through hole 46A and the second through hole 46B on the base portion 48C, the formation of the first adhesive member 50A in the groove 49A and the first adhesive member 50B in the groove 49B.

In the electronic device 1 according to the present embodiment, further, as illustrated in FIG. 18, the base portion 48C may be fixed to the front cover 30 via the adhesive member 50A arranged in the groove portion 49A, the first adhesive member 50B arranged in the groove portion 49B, and the second adhesive member 60, as illustrated in FIG. 18. That is, the base portion 48C having various components mounted thereon is attached to the front cover 30 via the two adhesive members: the first adhesive members 50A and 50B and the second adhesive member 60. Thus, the probability that water enters the electronic device 1 from the outside thereof may be further reduced.

According to the present embodiment, also, the second adhesive member 60 is arranged on the first adhesive member 50A in the base 48C, as illustrated in FIG. 18. Here, arranging the first adhesive member 50A and the second adhesive member 60 in different locations on the base portion 48C may increase the area of the base portion 48C. According to the present embodiment, the second adhesive member 60 is arranged on the first adhesive member 50A, thus reducing the area of the base portion 48C as compared to that having the first adhesive member 50A and the second adhesive member 60 provided in different locations.

### Electronic Device—Method of Manufacture

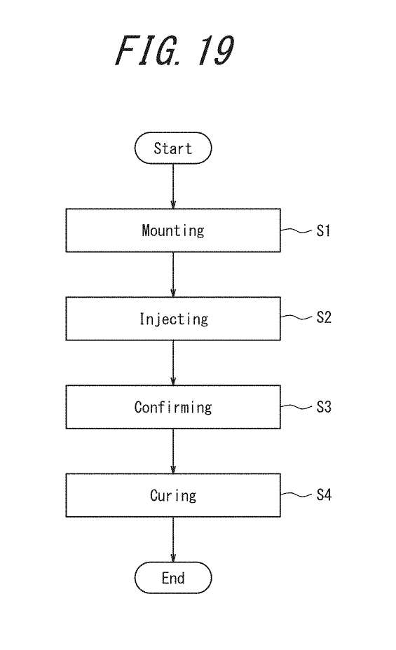

The method for manufacturing the electronic device 1 according to the present disclosure includes a mounting step S1, an injection step S2, a confirmation step S3, and a curing step S4, as illustrated in FIG. 19.

The mounting step S1 illustrated in FIG. 19 is a step of mounting the display 13 and the front cover 30 in the casing 40. In the mounting step S1, the accommodation portion 43 of the casing 40 accommodates the display 13 from the surface 13b of the display 13 as illustrated in FIG. 6. Further, the front cover 30 is attached to the casing 40 in such a manner that each of the first surfaces 42A and 42B of the casing 40 illustrated in FIG. 6 comes into close contact with the front cover 30. At this time, the second adhesive member 60 adheres the base portion 48C and the front cover 30 together as illustrated in FIG. 18.

The mounting step S1 as described above may form the clearances 1A and 1B between the display 13 and the accommodation portion 43 as illustrated in FIG. 6.

The injection step S2 illustrated in FIG. 19 is a step of injecting the liquid adhesive 51A from the opening 46A-2 of each of the first through holes 46A and the liquid adhesive 51B from the opening of each of the first through holes 46B on the outer surface 40a. When the liquid adhesive 51A is injected through the openings 46A-2, the liquid adhesive 51A may be injected into the clearance 1A illustrated in FIG. 6. When the liquid adhesive 51A is injected into the clearance 1A, the liquid adhesive 51A may also be injected into the groove 49A illustrated in FIG. 17 that communicates with the clearance 1A. Similarly, when the liquid adhesive 51B is injected through the opening of each of the first through holes 46B on the outer surface 40a, the liquid adhesive 51B is injected into the clearance 1B illustrated in FIG. 6 and the groove 49B illustrated in FIG. 17 communicating with the clearance 1B.

The confirmation step S3 is a step of confirming as to whether the liquid adhesives 51A and 51B have filled the clearances 1A and 1B, respectively. When the liquid adhesive 51A is viewed through the opening 47A-2 of the second through hole 47A illustrated in FIG. 5, it can be confirmed whether the liquid adhesive 51A has filled in the clearance 1A. Similarly, when the liquid adhesive 51B is viewed through the opening of the second through hole 47B-2 on the outer surface 40a, it can be confirmed whether the liquid adhesive 51B has filled in the clearance 1B.

The confirmation step S3 as described above enables reliable filling of the liquid adhesives 51A and 51B in the clearances 1A and 1B, respectively.

The curing step S4 is a step of curing the liquid adhesives 51A and 51B such that the first adhesive members 50A and 50B are formed between the display 13 and the accommodation portion 43. In the curing step S4, a curing method suitable for the liquid adhesives 51A and 51B may be employed.

For example, when the liquid adhesives 51A and 51B are moisture-curable adhesives, the liquid adhesives 51A and 51B may be cured by being brought into reaction with moisture in the air. For example, when the liquid adhesives 51A and 51B are thermosetting adhesives, the liquid adhesives 51A and 51B may be cured by being heated. For example, when the liquid adhesives 51A and 51B are ultraviolet curable adhesives, the liquid adhesives MA and MB may be cured by being irradiated with ultraviolet rays.

In the method for manufacturing the electronic device 1 according to the present embodiment, as described above, in the clearances 1A and 1B formed in the mounting step S1, the first adhesive members 50A and 50B are formed in the injection step S2 and the curing step S4. Thus, the method for manufacturing the electronic device 1 according to the present embodiment eliminates the necessity to provided dedicated spaces to arrange the first adhesive members 50A and 50B therein in the casing 40. Thus, according to the present embodiment, an improved method for manufacturing the electronic device 1 is provided.

Although the present disclosure has been described based on the figures and the embodiment, it is to be appreciated that those skilled in the art may easily conceive of various variations or modifications on the basis of the present disclosure. Accordingly, such variations and modifications are included in the scope of the present disclosure. For example, a function included in each means or each step may be rearranged avoiding a logical inconsistency, such that a plurality of means or steps are combined or divided.

1. An electronic device comprising:
a display;
a cover member that covers one surface of the display;
a casing that has a peripheral portion including a first surface in close contact with the cover member, and an accommodation portion that accommodates the display from the other surface of the display; and
a first adhesive member arranged in a first direction between the display and the accommodation portion.

2. The electronic device according to claim 1,
wherein the accommodation portion has a second surface in close contact with the other surface of the display and a third surface that couples the first surface and the second surface together, and
the first adhesive member is arranged between the third surface and a surface of the display that faces the third surface.

3. The electronic device according to claim 2,
wherein the casing further includes a first through hole that communicates with an outer surface opposite to a side where the accommodation portion is located and the third surface.

4. The electronic device according to claim 3,
wherein the casing further includes a second through hole that communicates with the outer surface and the third surface and is different from the first through hole.

5. The electronic device according to claim 4,
wherein an area of an opening of the second through hole on the outer surface is smaller than an area of an opening of the first through hole on the outer surface.

6. The electronic device according to claim 4,
wherein an area of an opening of the second through hole on the outer surface is smaller than an area of an opening of the second through hole on the third surface.

7. The electronic device according to claim 6,
wherein the opening of the second through hole on the third surface has a concave shape that opens toward the cover member.

8. The electronic device according to any one of claim 2,
wherein the casing also has a base located between a peripheral portion and the accommodation portion in a second direction different from the first direction, and
the base includes a groove formed by extending the third surface in the second direction.

9. The electronic device according to any one of claim 3,
wherein the casing also has a base located between a peripheral portion and the accommodation portion in a second direction different from the first direction, and
the base includes a groove formed by extending the third surface in the second direction.

10. The electronic device according to any one of claim 4,
wherein the casing also has a base located between a peripheral portion and the accommodation portion in a second direction different from the first direction, and
the base includes a groove formed by extending the third surface in the second direction.

11. The electronic device according to claim 8,
further comprising a second adhesive member that adheres the base and the cover member together.

12. The electronic device according to claim 11,
wherein the second adhesive member is a double-sided adhesive tape.

13. A method for manufacturing an electronic device comprising:
mounting a display and a cover member covering one surface of the display in a casing that has a peripheral portion including a first surface in close contact with the cover member, and an accommodation portion that accommodates the display from the other surface of the display;
injecting a liquid adhesive into a clearance formed between the display and the accommodation portion; and
curing the liquid adhesive to form a first adhesive member arranged between the display and the accommodation portion.
